(19) United States
(12) Patent Application Publication
(10) Pub. No.: US 2014/0057051 A1
(43) Pub. Date: Feb. 27, 2014

(54) PROCESS AND APPARATUS FOR PRODUCING FLUORINATED ORGANOSILICON COMPOUND THIN FILM

(71) Applicant: Asahi Glass Company, Limited, Chiyoda-ku (JP)

(72) Inventors: Ryosuke KATO, Chiyoda-ku (JP); Masao Miyamura, Chiyoda-ku (JP); Tamotsu Morimoto, Chiyoda-ku (JP)

(73) Assignee: Asahi Glass Company, Limited, Chiyoda-ku (JP)

(21) Appl. No.: 14/067,197

(22) Filed: Oct. 30, 2013

Related U.S. Application Data
(63) Continuation of application No. PCT/JP2012/061915, filed on May 9, 2012.

(30) Foreign Application Priority Data
May 10, 2011 (JP) 2011-105590

(51) Int. Cl. C23C 16/448

(52) U.S. Cl. CPC C23C 16/448
USPC 427/255.6; 118/726

(57) ABSTRACT

To provide a process and apparatus whereby a fluorinated organosilicon compound thin film having high durability can be produced, and a film formation step can be carried out continuously. A process for producing a fluorinated organosilicon compound thin film, which comprises the following steps (a) to (c) sequentially in this order, and an apparatus useful for the process:
(a) a heating step of heating a fluorinated organosilicon compound in a heating container to a vapor deposition initiation temperature,
(b) a pretreatment step of discharging a vapor from the fluorinated organosilicon compound after reaching the vapor deposition initiation temperature, and
(c) a deposition step of forming a fluorinated organosilicon compound thin film by supplying a vapor of the fluorinated organosilicon compound after the pretreatment step on a substrate in a vacuum chamber.

### TECHNICAL FIELD

The present invention relates to a process and apparatus for producing a fluorinated organosilicon compound thin film.

### BACKGROUND ART

Display glasses, optical elements, hygienic instruments, etc. are likely to be contacted by human fingers and thus likely to be stained by fingerprints, sebum, sweat, etc. And, such stains may not easily be wiped off and may become distinct depending upon lighting conditions, whereby there has been a problem that the visibility or aesthetic appearance is thereby impaired.

In order to solve such a problem, a method has been known wherein an antifouling film made of a fluorinated organosilicon compound, is formed on the surface of such components or instruments.

For example, Patent Document 1 discloses a method for forming a film by vapor deposition wherein, as a vaporization source, one having the raw material impregnated to porous ceramic pellets and dried, is used.

However, in a case where a raw material dried before introduced into a vapor deposition device is used as a vaporization source like this, the raw material substance becomes unstable, whereby there has been a problem such that the performance of the obtainable antifouling film is not stable, and the yield tends to be low. Further, a pelletizing step is required, which has created an additional cost.

Further, Patent Document 2 discloses a method wherein a solution containing a fluorinated alkyl group-containing organosilicon compound is, as it is, put in a container and heated, or one having the raw material impregnated to a porous metal powder-sintered filter is heated by electron beams, to form a thin film of the compound on a substrate.

However, in the invention disclosed in Patent Document 2, when the raw material is heated for at least the predetermined time, the durability of the obtainable antifouling film tends to be low. Therefore, there has been a problem such that the thickness of the film to be produced, is limited, or it is not possible to produce a highly durable film constantly.

Further, in each method disclosed in Patent Documents 1 and 2, the productivity has been low, since it is required to carry out the operation in a batch system by setting the raw material in such a very small amount that vaporizes in a few tens seconds after heating. Further, in order to raise the temperature within a predetermined time, an apparatus to be used, is rather limited, which has been a cause for a high cost.

As described above, by such conventional film-forming methods, it has been not possible to produce an antifouling film having durability continuously and constantly.

### PRIOR ART DOCUMENTS

### Patent Documents

Patent Document 1: JP-A-2009-175500
Patent Document 2: JP-A-2008-107836

### DISCLOSURE OF INVENTION

### Technical Problems

In view of the above-described problems of the prior art, it is an object of the present invention to provide a process and apparatus whereby a fluorinated organosilicon compound thin film having high durability can be produced, and the film formation can be carried out continuously.

### Solution to Problems

In order to solve the above problems, the present invention provides a process for producing a fluorinated organosilicon compound thin film, which comprises the following steps (a) to (c) sequentially in this order:

(a) a heating step of heating a fluorinated organosilicon compound in a heating container to a vapor deposition initiation temperature,

(b) a pretreatment step of discharging a vapor from the fluorinated organosilicon compound after reaching the vapor deposition initiation temperature, and

(c) a deposition step of forming a fluorinated organosilicon compound thin film by supplying a vapor of the fluorinated organosilicon compound after the pretreatment step on a substrate in a vacuum chamber.

Further, the present invention provides an apparatus for producing a fluorinated organosilicon compound thin film, which comprises a heating container for heating a fluorinated organosilicon compound, a vacuum chamber for forming a film by supplying a vapor of the fluorinated organosilicon compound from the heating container on a substrate, and a piping connecting the heating container and the vacuum chamber, wherein the heating container or the piping is provided with a discharge pipe capable of discharging a vapor from the heating container.

### Advantageous Effects of Invention

At the time of forming a fluorinated organosilicon compound thin film by vapor deposition, the present invention has a pretreatment step wherein after a fluorinated organosilicon compound as the vaporization source is heated to a vapor deposition initiation temperature, a part of its vapor is discharged out of the system. By such a pretreatment step, it is possible to remove low molecular weight components, etc. in the fluorinated organosilicon compound, which are influential over the durability of the film, and the composition of the raw material vapor to be supplied from the vaporization source, is stabilized. Therefore, it becomes possible to form a fluorinated organosilicon compound thin film having high durability constantly.

### BRIEF DESCRIPTION OF DRAWINGS

FIG. 1 is an illustration diagram of a second embodiment according to the present invention.

FIG. 2 is an illustration diagram of a modification example of the second embodiment according to the present invention.

FIG. 3 is an illustration diagram of a third embodiment according to the present invention.

FIG. 4 is an illustration diagram of a fourth embodiment according to the present invention.

FIG. 5 is an illustration diagram of a change in durability performance of a thin film due to the elapsed time after the temperature rise in Example of the present invention.

### DESCRIPTION OF EMBODIMENTS

Now, embodiments of the present invention will be described with reference to the drawings. However, it should be understood that the present invention is by no means limited to such embodiments, and it is possible to add various modifications and substitutions to the following embodiments without departing from the scope of the present invention.

### First Embodiment

Now, the process for producing a fluorinated organosilicon compound thin film according to the present invention will be described.

The process for producing a fluorinated organosilicon compound thin film of the present invention comprises the following steps (a) to (c) sequentially in this order:

(a) a heating step of heating a fluorinated organosilicon compound in a heating container to a vapor deposition initiation temperature,

(b) a pretreatment step of discharging a vapor from the fluorinated organosilicon compound after reaching the vapor deposition initiation temperature, and

(c) a deposition step of forming a fluorinated organosilicon compound thin film by supplying a vapor of the fluorinated organosilicon compound after the pretreatment step on a substrate in a vacuum chamber.

Here, the fluorinated organosilicon compound is a material for the vapor deposition source. Such a fluorinated organosilicon compound is not particularly limited so long as it is one to impart antifouling properties, water repellency and oil repellency, and various fluorinated organosilicon compounds may be used.

Further, in the step (b), after reaching the vapor deposition initiation temperature, a part of the vapor from the fluorinated organosilicon compound is discharged for a predetermined period of time.

Specifically, a fluorinated organosilicon compound having at least one group selected from the group consisting of a perfluoropolyether group, a perfluoroalkylene group and a perfluoroalkyl group, may be mentioned. Here, the perfluoropolyether group is meant for a bivalent group having a structure wherein a perfluoroalkylene group and an etheric oxygen atom are alternately bonded.

Specific examples of such a fluorinated organosilicon compound having at least one group selected from the group consisting of a perfluoropolyether group, a perfluoroalkylene group and a perfluoroalkyl group, may, for example, be compounds represented by the following formulae (I) to (IV).

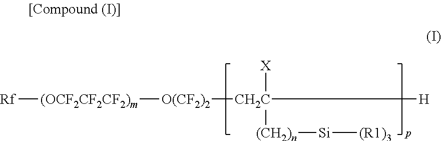

In the formula, Rf is a C₁₋₁₆ straight chain perfluoroalkyl group (the alkyl group may, for example, be a methyl group, an ethyl group, a n-propyl group, an isopropyl group or a n-butyl group), X is a hydrogen atom or a C₁₋₅ lower alkyl group (such as a methyl group, an ethyl group, a n-propyl group, an isopropyl group or a n-butyl group), R1 is a hydrolysable group (such as an amino group or an alkoxy group) or a halogen atom (such as fluorine, chlorine, bromine or iodine), m is an integer of from 1 to 50, preferably from 1 to 30, n is an integer of from 0 to 2, preferably from 1 to 2, and p is an integer of from 1 to 10, preferably from 1 to 8. The above expression “to” representing the numerical value range is used to include the numerical values before and after the expression as the lower limit value and the upper limit value, and unless otherwise specified, the expression “to” is hereinafter used to have the same meaning in this specification.

[Compound (II)]

C_{q}F_{2q+1}CH₂CH₂Si(NH₂)₃ (II)

Here, q is an integer of at least 1, preferably from 2 to 20.

As the compound represented by the formula (II), for example, n-trifluoro(1,1,2,2-tetrahydro)propyl silazane (n-CF₃CH₂CH₂Si(NH₂)₃) or n-heptafluoro(1,1,2,2-tetrahydro)pentyl silazane (n-C₃F₇CH₂CH₂Si(NH₂)₃) may be exemplified.

[Compound (III)]

C_{q′}F_{2q′+1}CH₂CH₂Si(OCH₃)₃ (III)

Here, q′ is an integer of at least 1, preferably from 1 to 20.

As the compound represented by the formula (III), 2-(perfluorooctyl)ethyltrimethoxysilane (n-C₈F₁₇CH₂CH₂Si(OCH₃)₃) may, for example, be exemplified.

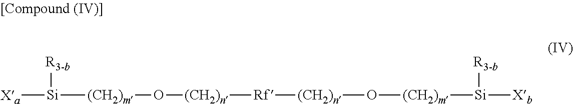

In the formula, Rf′ is a bivalent straight chain oxyperfluoroalkylene group represented by —(CₖF₂ₖ)O— (k is an integer of from 1 to 6), each R independently is a C₁₋₈ monovalent hydrocarbon group (such as a methyl group, an ethyl group, a n-propyl group, an isopropyl group or a n-butyl group), each X′ independently is a hydrolysable group (such as an amino group or an alkoxy group) or a halogen atom (such as fluorine, chlorine, bromine or iodine), each n′ independently is an integer of from 0 to 2 (preferably from 1 to 2), each m′ independently is an integer of from 1 to 5 (preferably from 1 to 2), and each of a and b independently is 2 or 3.

As a commercially available fluorinated organosilicon compound having at least one group selected from the group consisting of a perfluoropolyether group, a perfluoroalkylene group and a perfluoroalkyl group, KP-801 (trade name, manufactured by Shin-Etsu Chemical Co., Ltd), KY-178, KY-185, KY-130 (trade name, manufactured by Shin-Etsu Chemical Co., Ltd) or Optool (registered trademark) DSX (trade name, manufactured by Daikin Industries, Ltd.) may, for example, be preferably used.

Further, a fluorinated organosilicon compound is usually stored as mixed with a fluorinated solvent for stabilization. Therefore, it is preferred to carry out a step of removing such a solvent (medium) before the heating step. Specifically, this can be done by subjecting a solution of a fluorinated organosilicon compound to evacuation for a predetermined period of time, e.g. for at least about 10 hours. Such a step can also be carried out by introducing a fluorinated organosilicon compound solution into a heating container and then evacuating the interior of the heating container before the heating step. Otherwise, a solvent removing step may be carried out before the introduction of the compound into the heating container.

And, the substrate on which the fluorinated organosilicon compound thin film is to be formed, is not particularly limited, and various substrates made of glass, plastics, metals, etc., for which an antifouling film, a water repellent film or an oil repellent film is required, may be employed. Also with respect to its shape, the substrate is not limited to a flat one, and a molded or shaped one may also be used.

Now, each step of the process of the present invention will be described.

### (Heating Step)

The heating step (step (a)) is a step of heating a fluorinated organosilicon compound as a vapor deposition material which has been preliminarily introduced into a heating container, to a vapor deposition initiation temperature.

Here, the heating container may be any container so long as it has thermal resistance and pressure resistance, and for example, a crucible may be used. The amount of the fluorinated organosilicon compound to be introduced into the heating container is to be selected depending upon the amount of the substrate to be covered by the film, the film thickness, etc. and is not particularly limited.

And, the vapor deposition initiation temperature is a temperature selected within a temperature range of at least a temperature at which the vapor pressure becomes to be at a level where the vapor deposition source can supply the deposition raw material to the substrate under the deposition conditions. It varies depending upon the deposition conditions such as the vapor deposition source to be used, the background pressure, etc. and is suitably selected for use. It is particularly preferred that a temperature at which the required deposition rate is constantly obtainable is preliminarily determined by e.g. a preliminary test, and the vapor deposition initiation temperature is set to be such a temperature. If the temperature becomes too high, the fluorinated organosilicon compound may undergo a polymerization reaction in the raw material in the heating container, and if the polymerization reaction becomes predominant, it may present an influence to the performance of the film, or the deposition rate may be lowered. Therefore, it is preferred to select the vapor deposition initiation temperature within a range lower than the temperature at which the polymerization reaction becomes predominant. Specifically, the vapor deposition initiation temperature is preferably at least 200° C. and at most 320° C. in the case of fluorinated organosilicon compounds to be used in the present invention including the above-mentioned compounds represented by the formulae (I) to (IV).

The heating temperature in the heating step is not particularly limited so long as the temperature can be raised to the vapor deposition initiation temperature, and the rate of temperature rise is not particularly limited.

As a heating device for the heating step, various known devices including an electrically heating wire heater (resistance heating), a halogen lamp, a radiofrequency heating, etc. may be used, but from the viewpoint of efficiency in the temperature control or costs, it is preferred to carry out the heating by an electrically heating wire heater. Further, in order to prevent precipitation in a route from the heating container to jet orifices facing the substrate, it is preferred to simultaneously heat components constituting such a route, i.e. the piping, etc. connecting the heating container and the vacuum chamber.

### (Pretreatment Step)

The pretreatment step (step (b)) is a step of discharging a part of the vapor from the vapor deposition source after the fluorinated organosilicon compound as the vapor deposition material has reached the vapor deposition initiation temperature.

The deposition material, i.e. the fluorinated organosilicon compound used as the vapor deposition source, has a high molecular weight and has a molecular weight distribution, and therefore, at a stage immediately after it has reached the vapor deposition initiation temperature, its vapor contains readily vaporizing low molecular weight components and in some cases, further contains low boiling impurity components at a high ratio. By a study made by the present inventors, however, it has been found that if film formation is carried out by using the vapor containing such components, the durability of the obtained film becomes to be low. Therefore, this is a step to be carried out in order to reduce the ratio of such low molecular weight components, etc.

Now, the pretreatment step will be described specifically.

As mentioned above, the pretreatment step is carried out after the fluorinated organosilicon compound has reached the vapor deposition initiation temperature by the heating step and before initiation of the deposition step, by discharging a vapor generated from e.g. the heating container out of the system (i.e. out of the system such as the heating container, the piping extending from the heating container to the vacuum chamber, or the vacuum chamber), while maintaining the temperature. Thus, it is possible to remove or reduce low molecular weight components or low boiling impurity components generated from the vapor deposition source containing the fluorinated organosilicon compound and being influential to lower the performance of the film, before the film formation. This pretreatment step may be initiated immediately upon reaching the vapor deposition initiation temperature. However, it is preferred to carry out this step when the temperature has been stabilized upon expiration of e.g. about 5 to 15 minutes after reaching the vapor deposition initiation temperature.

Here, the discharging method is not particularly limited, and various methods may be employed so long as it is thereby possible to discharge the vapor to be discharged out of the system, without supplying it on the substrate. For example, the vapor may be supplied to the vacuum chamber before placing a substrate therein, so that the vapor is discharged out of the system from a discharge line connected to the vacuum chamber. However, so that low molecular weight components, etc. will not remain in the vacuum chamber, it is more preferred to discharge the vapor out of the system by using a discharge pipe which is provided on the heating container or on the piping from the heating container and which is connected to e.g. a vacuum pump.

The time for the pretreatment step is not particularly limited and is suitably selected depending upon the reaction conditions, the type of the fluorinated organosilicon compound, etc. That is, the necessary treating time varies depending upon the discharging ability of the apparatus, the operation conditions such as the amount of the raw material, etc.

As a method for setting the time for the pretreatment step, the following two methods may, for example, be exemplified. However, it is not limited to either one of these methods.

The first method is one to determine the treating time by carrying out, as a preliminary test as described later in Example, evaluation of the performances of thin films obtained by film formation by introducing a substrate into the vapor deposition apparatus every predetermined time without carrying out the pretreatment step after reaching the vapor deposition initiation temperature. More specifically, this method is one to take, as the time for the pretreatment step, a time until it becomes possible to constantly obtain a film with little change or change rate in water contact angle by carrying out a durability test of the obtained fluorinated organosilicon compound thin films.

Whereas, the second method is a method to determine the time by monitoring the change in the deposition rate by a film thickness meter. This method is one to utilize a phenomenon such that immediately after reaching the vapor deposition initiation temperature, low molecular weight components, etc. are supplied, whereby the deposition rate increases, but as the time passes, supply of hardly vaporizing high molecular weight components becomes predominant whereby the deposition rate tends to be low and stabilized. That is, firstly the deposition rate at the time when the vapor deposition initiation temperature has been reached, is measured and taken as the initial deposition rate. Then, the deposition rate is measured every predetermined time or continuously, whereby the time until the deposition rate becomes at most 30% of the initial deposition rate is taken as the time for the pretreatment step. Here, more preferably, the time until the deposition rate becomes at most 20% of the initial deposition rate is taken as the time for the pretreatment step. In a case where an adjustable valve is provided between the heating container and the manifold having jet orifices to spray the vapor of the fluorinated organosilicon compound to the substrate, the opening degree of the valve is kept to be constant during the monitoring of the deposition rate. Further, it is more preferred to measure the initial deposition rate at the time when the temperature has been stabilized upon expiration of from 5 to 15 minutes after reaching the vapor deposition initiation temperature.

Also in this second method, it is preferred to preliminarily determine the time for the pretreatment step by carrying out a preliminary test.

However, in a case where the vapor discharge in the pretreatment step is carried out by the evacuation system of the vacuum chamber, it is possible to suitably determine the termination timing from the value of the film thickness meter provided in the vacuum chamber, while carrying out the pretreatment step.

### (Deposition Step)

The deposition step (step (c)) is a step of forming a film by vapor deposition by supplying a vapor of the fluorinated organosilicon compound after the pretreatment step on a substrate disposed in a vacuum chamber.

The substrate may simply be introduced into the vacuum chamber prior to the deposition step, and the timing for the introduction into the vacuum chamber is not particularly limited. For example, it may be introduced into the apparatus even prior to the step (a) i.e. prior to the heating step. Or, it may be introduced immediately prior to the deposition step. However, in a case where the vapor discharge is carried out via the vacuum chamber in the pretreatment step, the substrate is introduced into the vacuum chamber after the pretreatment step.

And, the specific deposition conditions are selected depending upon the type of the fluorinated organosilicon compound to be used, the required film thickness, etc. However, it is preferred that at the time of supplying the vapor from the heating container, the temperature of the heating container is maintained at the vapor deposition initiation temperature.

Further, in a case where a sufficient amount of the fluorinated organosilicon compound is preliminarily introduced into the heating container, the deposition step can be carried out repeatedly while replacing the substrate. In such a case, the step (c) i.e. the deposition step may comprise the following steps (c1) to (c3), and by repeating these steps, the film formation on a substrate may be continuously carried out.

(c1) a step of introducing the substrate into the vacuum chamber,

(c2) a step of supplying the vapor from the fluorinated organosilicon compound on the substrate in the vacuum chamber to form the film, and

(c3) a step of withdrawing the film-formed substrate from the vacuum chamber.

Here, these steps are not necessarily required to be started from the step (c1), and the starting or termination step may be selected depending upon the situation. Specifically, for example, in a case where a substrate is preliminarily introduced into the vacuum chamber prior to the deposition step, the operation is to be started from the step (c2).

According to the process of the present invention, even when the film formation is carried out repeatedly like this, a thin film with a stabilized performance can be formed. Further, by carrying out the film formation continuously like this, it becomes possible to increase the productivity.

Further, it is also possible that after termination of the step (c), the following step (d) is further carried out, and the steps (a) to (d) are repeated:

(d) a step of adding the fluorinated organosilicon compound to the heating container.

In such a case, the fluorinated organosilicon compound is added to the heating container, whereby the film formation can be carried out continuously, and it is possible to improve the productivity.

The method for adding the fluorinated organosilicon compound may, for example, be such that a fluorinated organosilicon compound solution tank is connected to the heating container by a piping having a valve, so that the compound can be suitably added by opening and shutting the valve. In such a case, it is preferred that the organosilicon compound in the tank is preliminarily subjected to removal of a solvent.

Here, the timing for termination of the step (c) may be judged by various methods. For example, it may be judged based on a time elapsed from the termination time of the step (b) i.e. the pretreatment step. This is a method wherein a time until the amount of the fluorinated organosilicon compound remaining in the heating container becomes to be a predetermined value, e.g. from 10 to 20% of the volume of the heating container, is preliminarily investigated by e.g. a preliminary test, so that the step (c) is terminated upon expiration of such a time after the pretreatment step. By this method, it is not necessary to provide a sensor anew on e.g. the heating container, such being advantageous from the viewpoint of costs.

Another method may be such that a device for detecting the remaining amount of the fluorinated organosilicon compound in the heating container is provided, so that the timing for termination of the step (c) is judged based on a signal from the device for detecting the remaining amount. As the device for detecting the remaining amount, various methods may be used. For example, it may be a method of directly detecting the remaining amount by providing a weight scale or a liquid-level gauge in the heating container, or a method of detecting the remaining amount from a change of the deposition rate.

In the case of using a device for detecting the remaining amount, it becomes possible to more accurately detect the remaining amount of the organosilicon compound in the heating container. Therefore, it becomes possible to more suitably judge the timing for adding the fluorinated organosilicon compound to the heating container and thereby to prevent a damage of the container due to e.g. heating the empty container.

### Second Embodiment

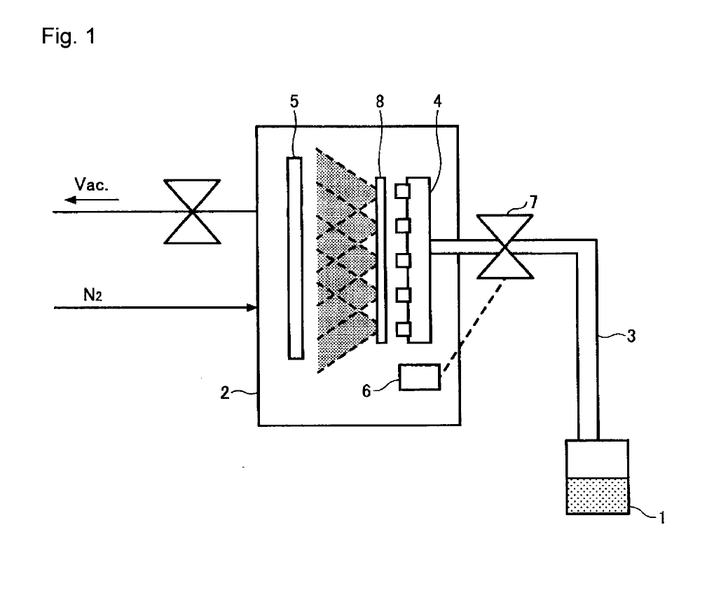

An embodiment employing an apparatus shown in FIG. 1 which is useful for the process for producing a fluorinated organosilicon compound thin film of the present invention, will be described as the second embodiment with reference to FIG. 1.

The apparatus shown in FIG. 1 comprises a heating container 1 for heating a fluorinated organosilicon compound as the vapor deposition source, a vacuum chamber 2 for forming a film by supplying a vapor of the fluorinated organosilicon compound from the heating container on a substrate 5, and a piping 3 connecting the heating container 1 and the vacuum chamber 2.

The heating container 1 is not limited with respect to its size or material, but since it may be subjected to a negative pressure, it is preferably one having a pressure resistance in addition to a thermal resistance.

In the vacuum chamber 2, a manifold 4 connected to the piping 3 from the heating container and having jet orifices for spraying the vapor from the heating container to the substrate, and a substrate-holding member not shown, are provided. Here, the substrate-holding member is a member capable of holding the substrate 5 so that jet orifices of the manifold 4 and the substrate 5 face each other. Further, in the vacuum chamber, a line connected to a vacuum pump, and a line to supply a gas, are provided. The type of the gas is not particularly limited, and for example, a line to supply an inert gas such as nitrogen, may be provided.

The jet orifices of the manifold 4 are not limited to such a construction as in a common vapor deposition apparatus wherein the spraying direction is in a vertical direction, and they may simply be required to be disposed to face the substrate. Specifically, in a case where the jet orifices are provided to spray the vapor from the heating container in a horizontal direction, as shown in FIG. 1, or even in a case where they are provided to spray the vapor in a downward direction, it is possible to uniformly form a film according to the present invention. Particularly, it is preferred that as shown in FIG. 1, jet orifices are provided in the manifold 4 so that they spray the vapor from the heating container in a horizontal direction. In such a case, manifolds may be set on both sides of a substrate to face each other with the substrate interposed between them, whereby uniform thin films will be formed simultaneously on both sides of the substrate, and the productivity will be improved.

Further, it is preferred that also the manifold portion is provided with a heater for heating in order to prevent condensation of the vapor from the heating container. Further, in the drawing, a cooling plate 8 is provided between the manifold 4 and the substrate 5, and it is one to prevent transmission of radiation heat from the manifold portion to the substrate. Such a construction is preferred for the protection of the substrate.

With respect to the piping 3, in order to prevent condensation of the vapor from the heating container en route, it is preferred to heat the piping together with the heating container.

Further, in order to control the deposition rate, it is preferred that an adjustable valve 7 is provided at a predetermined position of the piping 3, and the opening degree of the adjustable valve 7 is adjusted based on a value detected by a film-thickness meter 6 provided in the vacuum chamber 2. By such a construction, it becomes possible to control the amount of the vapor of the fluorinated organosilicon compound to be supplied to the substrate and to form a thin film having a desired thickness on the substrate accurately.

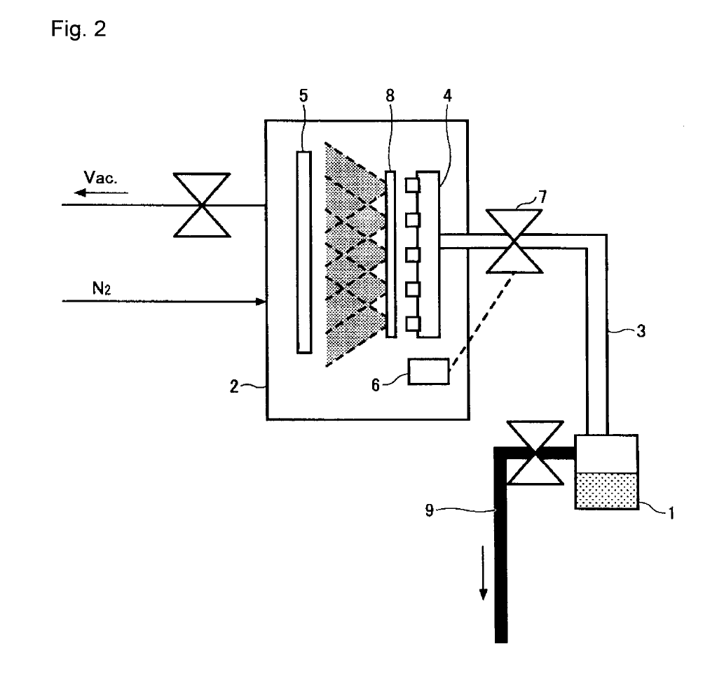

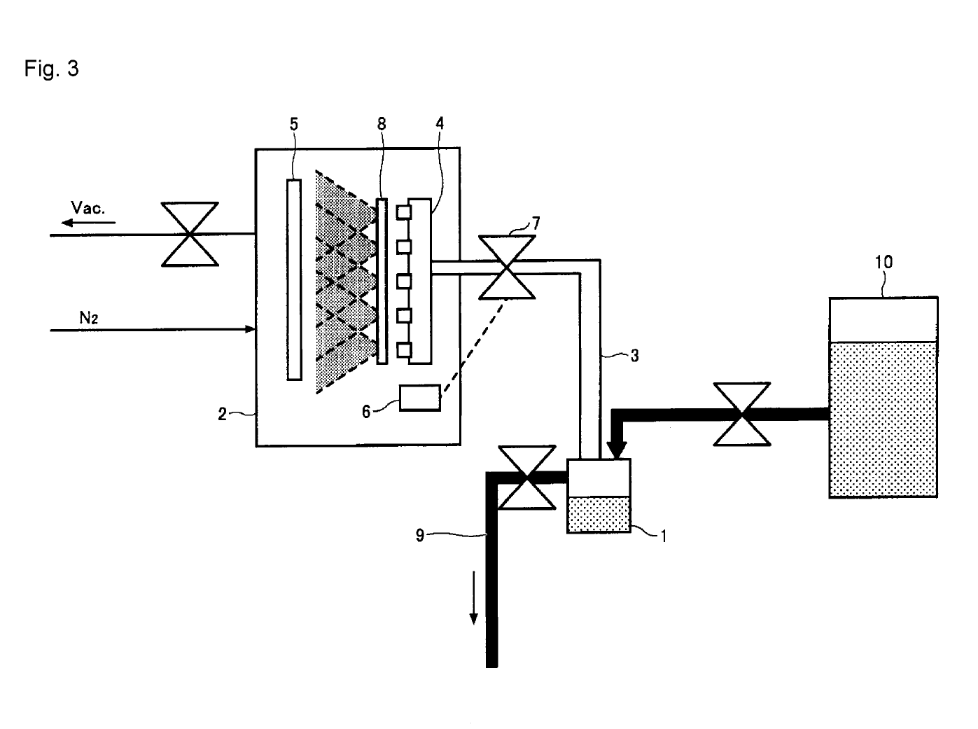

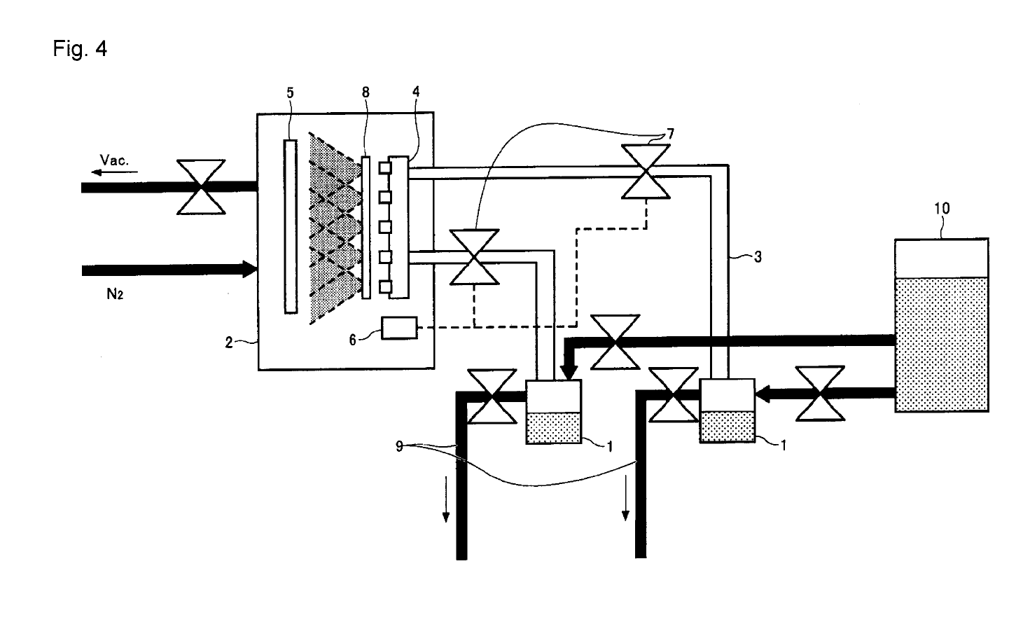

A modification example of the second embodiment will be described with reference to FIG. 2. In FIG. 2, members common to FIG. 1 are identified by the same numerals (hereinafter the same applies to FIGS. 3 and 4). As shown in FIG. 2, the heating container 1 is provided with a discharge pipe 9 connected to a vacuum pump not shown. In this embodiment, at a predetermined position of the heating container 1 or the piping 3, a discharge pipe capable of discharging a vapor from the heating container may be disposed. By such a construction, the pretreatment step can be carried out without via the vacuum chamber, whereby it is possible to prevent low molecular weight components, etc. from remaining in the vacuum chamber, such being preferred.

### Third Embodiment

In this embodiment, a means to supply a fluorinated organosilicon compound as a vapor deposition source, is further provided.

Specifically, as shown in FIG. 3, this apparatus has a fluorinated organosilicon compound solution tank 10 connected to the heating container 1. Therefore, it becomes possible to suitably supply the raw material to the heating container and thereby to conduct the operation continuously for a longer period of time.

Further, as described in the modification example of the second embodiment, also in this embodiment, it is preferred that the heating container 1 is provided with a discharge pipe 9 as shown in FIG. 3, so that the pretreatment step can be carried out by the discharge pipe 9 provided on the heating container 1, after supplying the raw material and heating it to a predetermined temperature.

### Fourth Embodiment

In this embodiment, as shown in FIG. 4, the third embodiment is further modified to have a plurality of heating containers. To each heating container 1, a discharge pipe 9 and a fluorinated organosilicon compound solution tank 10 are connected. It is thereby possible that while the vapor is supplied to the vacuum chamber 2 from one heating container 1, the heating step and the pretreatment step are carried out in the other heating container 1. Thus, it is possible to conduct the operation while switching the two heating containers, and it becomes possible to carry out the film formation more continuously.

Further, in this embodiment, the number of heating containers 1 is 2, but it may be 3 or more.

Further, in the above second to fourth embodiments, it is further possible that to the vacuum chamber 2, a front chamber for introducing the substrate to the vacuum chamber 2, and a substrate-withdrawing chamber for withdrawing the film-formed substrate from the vacuum chamber, are connected. In such a case, the front chamber and the substrate-withdrawing chamber may be individually constructed to be capable of evacuation and venting, so that vacuuming for introduction of the substrate or venting for the withdrawal may be carried out simultaneously while carrying out the deposition step in the vacuum chamber, whereby it becomes possible to further increase the productivity.

### Example

Now, the present invention will be described with reference to specific Example, but it should be understood that the present invention is by no means limited to this Example.

In this Example, by means of the vapor deposition apparatus as shown in FIG. 1, a fluorinated organosilicon compound thin film as an antifouling film was formed on a glass substrate in the following procedure, and its evaluation was carried out.

The experimental procedure in this Example will be described below.

### (Selection of Time for Pretreatment Step)

As a preliminary test, the time for the pretreatment step was selected by the following method.

Firstly, 75 g of a solution of Optool (registered trademark) DSX (trade name, manufactured by Daikin Industries, Ltd.) being a fluorinated organosilicon compound having at least one group selected from the group consisting of a perfluoropolyether group, a perfluoroalkylene group and a perfluoroalkyl group, as a vapor deposition material, was introduced into a crucible as the heating container. Thereafter, the interior of the crucible was evacuated for 10 hours by a vacuum pump to remove the solvent in the solution.

Then, after the solvent-removal treatment, the crucible was heated to 270° C. i.e. the vapor deposition initiation temperature of the above Optool. And after waiting for 10 minutes until the temperature was stabilized after reaching 270° C., a glass substrate was introduced into the vacuum chamber, and the deposition step was carried out so that the film thickness would be 15 nm. The deposition step was terminated when the film thickness became 15 nm, and the substrate was taken out from the vacuum chamber. In order to evaluate the change in the durability performance of the thin film due to an elapsed time after the temperature rise, with respect to each sample, the holding time after reaching 270° C. was changed every predetermined time, and upon expiration of every predetermined time, introduction of the substrate, deposition treatment and withdrawal of the substrate were likewise repeated.

Here, as a glass substrate, soda lime glass with a size of 100 mm square and a thickness of 1.1 mm was used. The glass substrate was one which was preliminarily subjected to cleaning treatment of its surface. As the specific procedure, the surface of each substrate was cleaned sequentially in the order of [1] 15 minutes of acetone ultrasonic cleaning, [2] 15 minutes of ethanol ultrasonic cleaning and [3] 15 minutes of pure water ultrasonic cleaning.

Each substrate having a film formed by the deposition step was taken out of the vacuum chamber, then placed on a hot plate so that the film side faced upward and subjected to a thermal treatment in the atmosphere at 150° C. for 60 minutes, and then subjected to a durability test of the film.

The procedure of the durability test of the film will be described.

On the glass substrate having the film formed by the above method, 1 μL of pure water was dropped and its contact angle was measured and taken as the initial water contact angle.

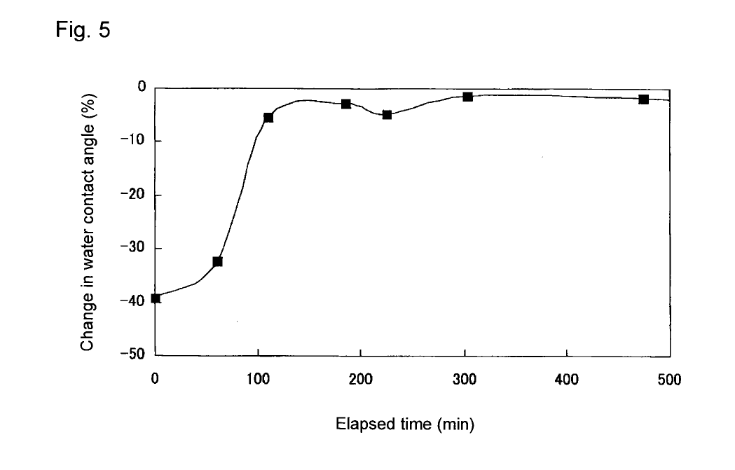

Then, the thin film-formed side of each substrate was rubbed with #000 steel wool for 2,000 reciprocations i.e. 4,000 times at a speed of 16 mm/sec while exerting a pressure of 500 g/cm². Thereafter, the contact angle was measured in the same manner as in the case of the initial water contact angle. And, the change (%) in the water contact angle from the initial water contact angle was calculated. The results are shown in FIG. 5.

In FIG. 5, the abscissa represents the elapsed time (min) from the time when the temperature was stabilized after the vapor deposition material in the crucible reached 270° C. And, the relation between the time when the substrate was introduced into the vacuum chamber and the change in water contact angle of the thin film formed on the substrate, was plotted.

From FIG. 5, it is evident that in a case where the substrate was introduced for deposition within 100 minutes from the time when the temperature was stabilized after the vapor deposition material in the crucible reached 270° C., the performance was substantially low with the change in water contact angle being from −30 to −40%. Whereas, in a case where the elapsed time was at least 110 minutes, little change was observed in the change in water contact angle, and it can be said that a film having high durability with little change in performance was obtained.

In this Example, it was an object to produce an antifouling film with its durability substantially not changeable, and therefore, from the foregoing preliminary test results, it was decided to carry out the pretreatment step in this Example for 110 minutes after reaching 270° C.

Whereas, in a conventional method, e.g. in a case where vapor deposition is conducted by using solid pellets as the vapor deposition source, the vapor deposition is carried out within 110 minutes after the vapor deposition material has reached 270° C. That is, the actual vapor deposition to form a film is carried out at the time of the pretreatment step in this Example, whereby it is considered that the film will be inferior in the durability.

### (Formation of Antifouling Film on Glass Substrate)

Based on the above preliminary test results, formation of an antifouling film on a substrate was carried out. The operation was carried out in the same procedure as in the above-described (Selection of time for pretreatment step) except that after the temperature was stabilized after the vapor deposition material was heated to 270° C., the substrate was not immediately introduced into the vacuum chamber, but the pretreatment step was carried out for 110 minutes, and then, the deposition step was carried out. Further, the evaluation was carried out in the same manner.

Here, the pretreatment step was carried out by utilizing the evacuation system of the vacuum chamber. At that time, the change in the deposition rate was monitored, whereby the deposition rate after carrying out the pretreatment step for 110 minutes was found to be lowered to a level of at most 20% of the initial deposition rate measured after waiting for 10 minutes until the temperature was stabilized after the vapor deposition material was heated to 270° C. Further, it was confirmed that thereafter, the deposition rate was stable during the deposition step.

The above results are shown in Table 1. In the Table, the “Time after termination of pretreatment step” represents a time when the substrate was introduced into the vacuum chamber, as counted from the time for termination of the pretreatment step i.e. from the time when 110 minutes were expired from the stabilization of the temperature after the temperature rise. For example, one with “75 min” means such a sample that the substrate was introduced into the vacuum chamber to initiate the deposition step upon expiration of 75 minutes after termination of the pretreatment step.

Further, the “Judgment” was such that as a result of the durability test, one with the change in water contact angle being at most 10% was judged to be “◯” (good).

TABLE 1

| Time after | Initial | Water contact | Change in | |
|---|---|---|---|---|
| termination of | water contact | angle after | water contact | |
| pretreatment | angle | rubbing | angle | |
| step [min] | [°] | [°] | [%] | Judgment |
| 0 | 113.9 | 107.8 | −5.4 | ◯ |
| 75 | 114.8 | 111.5 | −2.9 | ◯ |
| 115 | 113.12 | 107.8 | −4.7 | ◯ |
| 193 | 113.9 | 112.3 | −1.4 | ◯ |
| 365 | 113.2 | 111.1 | −1.9 | ◯ |
| 538 | 113.2 | 109.16 | −3.6 | ◯ |

The above results show that films including one formed immediately after termination of the pretreatment step to one formed upon expiration of about 500 minutes thereafter all exhibit high durability such that the change in water contact angle is at most about 5%. That is, it is evident that according to the present invention, it is possible to produce a film having high durability constantly.

### INDUSTRIAL APPLICABILITY

According to the present invention, it is possible to form a fluorinated organosilicon compound thin film having high durability constantly and thus is useful for the production of e.g. an antifouling film-coated substrate, a water repellent film-coated substrate or an oil repellent film-coated substrate, wherein a fluorinated organosilicon compound thin film is formed.

This application is a continuation of PCT Application No. PCT/JP2012/061915, filed on May 9, 2012, which is based upon and claims the benefit of priority from Japanese Patent Application No. 2011-105590 filed on May 10, 2011. The contents of those applications are incorporated herein by reference in its entirety.

### REFERENCE SYMBOLS

1: Heating container
2: Vacuum chamber
3: Piping
4: Manifold
5: Substrate
6: Film thickness monitor
7: Adjustable valve
9: Discharge pipe
10: Fluorinated organosilicon compound solution tank

What is claimed is:

1. A process for producing a fluorinated organosilicon compound thin film, which comprises the following steps (a) to (c) sequentially in this order:
(a) a heating step of heating a fluorinated organosilicon compound in a heating container to a vapor deposition initiation temperature,
(b) a pretreatment step of discharging a vapor from the fluorinated organosilicon compound after reaching the vapor deposition initiation temperature, and
(c) a deposition step of forming a fluorinated organosilicon compound thin film by supplying a vapor of the fluorinated organosilicon compound after the pretreatment step on a substrate in a vacuum chamber.

2. The process for producing a fluorinated organosilicon compound thin film according to claim 1, wherein the step (c) comprises:
(c1) a step of introducing the substrate into the vacuum chamber,
(c2) a step of supplying a vapor of the fluorinated organosilicon compound after the pretreatment step on the substrate in the vacuum chamber to form the film, and
(c3) a step of withdrawing the film-formed substrate from the vacuum chamber, wherein the steps (c1) to (c3) are repeated to continuously form the film on a substrate.

3. The process for producing a fluorinated organosilicon compound thin film according to claim 1, which has, after termination of the step (c), (d) a step of adding a fluorinated organosilicon compound into the heating container, wherein the steps (a) to (d) are repeated.

4. The process for producing a fluorinated organosilicon compound thin film according to claim 1, wherein the timing for termination of the step (c) is judged based on a time elapsed from the termination time of the step (b).

5. The process for producing a fluorinated organosilicon compound thin film according to claim 1, wherein the timing for termination of the step (c) is judged based on a signal from a device for detecting the remaining amount of the fluorinated organosilicon compound in the heating container.

6. The process for producing a fluorinated organosilicon compound thin film according to claim 1, wherein the step of forming a fluorinated organosilicon compound thin film is a deposition step by means of a vapor deposition method.

7. An apparatus for producing a fluorinated organosilicon compound thin film, which comprises:
a heating container for heating a fluorinated organosilicon compound,
a vacuum chamber for forming a film by supplying a vapor of the fluorinated organosilicon compound from the heating container on a substrate, and
a piping connecting the heating container and the vacuum chamber, wherein the heating container or the piping is provided with a discharge pipe capable of discharging a vapor from the heating container.

8. The apparatus for producing a fluorinated organosilicon compound thin film according to claim 7, wherein the piping is provided with an adjustable valve, and the opening degree of the adjustable valve is adjusted based on a value detected by a film-thickness monitor provided in the vacuum chamber.

9. The apparatus for producing a fluorinated organosilicon compound thin film according to claim 7, wherein to the heating container, a fluorinated organosilicon compound solution tank is connected.

10. The apparatus for producing a fluorinated organosilicon compound thin film according to claim 7, wherein to the vacuum chamber, a front chamber for introducing the substrate to the vacuum chamber, and a substrate-withdrawing chamber for withdrawing the film-formed substrate from the vacuum chamber, are connected, and the front chamber and the substrate-withdrawing chamber are individually constructed to be capable of evacuation and venting.

11. The apparatus for producing a fluorinated organosilicon compound thin film according to claim 7, wherein in the vacuum chamber, a manifold for spraying the vapor from the heating container to the substrate, and a substrate-holding member capable of holding the substrate so that jet orifices of the manifold and the substrate face each other, and the jet orifices are formed in the manifold so that the vapor from the heating container is sprayed in a horizontal direction.

12. The apparatus for producing a fluorinated organosilicon compound thin film according to claim 7, wherein the vacuum chamber is a vacuum chamber of a vapor deposition apparatus.
